(19) United States
(12) Patent Application Publication
(10) Pub. No.: US 2021/0366207 A1
(43) Pub. Date: Nov. 25, 2021

(54) DIAGNOSTIC SYSTEM AND METHOD FOR PROCESSING DATA OF A MOTOR VEHICLE

(71) Applicant: MS Motorservice International GmbH, Neuenstadt Am Kocher (DE)

(72) Inventors: Joerg SEIDEL, Steinbach (DE); Sven ZEITLER, Ditzingen (DE)

(73) Assignee: MS Motorservice International GmbH, Neuenstadt Am Kocher (DE)

(21) Appl. No.: 17/045,251

(22) PCT Filed: Mar. 12, 2019
(86) PCT No.: PCT/EP2019/056173

§ 371 Date: Oct. 5, 2020

(30) Foreign Application Priority Data
Apr. 18, 2018 (DE) 10 2018 109 195.8

(51) Int. Cl. G07C 5/00; G07C 5/08

(52) U.S. Cl. CPC G07C 5/006; G07C 5/085; G07C 5/008

(57) ABSTRACT

A method for processing data of a motor vehicle in a diagnostic system, diagnostic system and computer program are disclosed. In an embodiment, the diagnostic system is configured to access diagnostic data for at least one component of the motor vehicle, the diagnostic data linking the information about at least one operating parameter of the motor vehicle with information about the at least one component. The diagnostic system is configured to evaluate information about a probability of an occurrence of a fault in the motor vehicle depending on the diagnostic data and depending on the information about the at least one operating parameter.

### FIELD OF THE INVENTION

The disclosure relates to a diagnostic system for processing data of a motor vehicle.

The disclosure also relates to a method of operating such a diagnostic system.

Diagnostic systems and methods of the type mentioned above are well known and have a high degree of specialization.

### STATE OF THE ART

It is the object of the present invention to improve a diagnostic system and a method of the kind mentioned above so that the above-mentioned disadvantages are reduced or avoided and utility in use is increased.

### DESCRIPTION OF THE INVENTION

Preferred embodiments suggest a diagnostic system for processing data of a motor vehicle, which is configured to access diagnostic data for at least one component of the motor vehicle, wherein the diagnostic data links information about at least one operating parameter of the motor vehicle with information about the at least one component, wherein the diagnostic system is configured to evaluate information about a probability of an occurrence of a fault in the motor vehicle depending on the diagnostic data and depending on the information about the at least one operating parameter. By providing the diagnostic system based on information about components, an efficient diagnosis of, for example, faults which occur during the operation of the motor vehicle can be carried out depending on the probability of occurrence of the faults of individual components. The provision of the diagnostic system particularly advantageously allows a flexible execution of a diagnosis across manufacturers and vehicles. With preferred embodiments, it may be provided that at least a part of the diagnosis or the entire diagnosis is carried out by the diagnostic system.

With preferred embodiments, it is provided that the diagnostic system comprises at least one expert system which is configured to evaluate the information about a probability by determining the information about the probability depending on information about an observation of a technician or a measured value, in particular voltage, current, capacity, inductance of a component. In this way, for an efficient diagnosis of faults and an evaluation of operating parameters of a motor vehicle, for example, useful knowledge can be stored in a machine-processable form and can be provided for a data processing device, for example.

With other preferred embodiments, it is provided that the diagnostic system comprises at least one AI subsystem which is configured to evaluate the information about a probability by determining the information about the probability depending on information about an observation by a technician or a measured value, in particular voltage, current, capacitance, inductance of a component. This can significantly increase the flexibility of the operation of the system and the reliability of diagnosis compared to conventional systems. While conventional systems allow or suggest the sequential processing of individual fault codes or fault symptoms, for example, the diagnostic system can carry out a diagnosis much more efficiently using AI-based algorithms, can in particular also learn from its own operation or from information obtained during operation (e.g. from the data processing device), and thus, can further improve its function.

With other preferred embodiments, it is provided that the diagnostic system is configured to receive vehicle data read out via an OBD-II interface. This standard interface allows interaction with a large number of motor vehicles from different manufacturers.

With other preferred embodiments, it is provided that the diagnostic system is configured to receive vehicle information of the motor vehicle, wherein the vehicle information comprises at least one of the following elements: a vehicle identification number, VIN (in German: FIN, Fahrzeug-Identifizierungsnummer), identifying the motor vehicle, operating data characterizing an operation of at least one component of the motor vehicle, one or more fault codes characterizing a fault of at least one component of the motor vehicle. A comparatively low bandwidth is advantageously required for the transmission of the vehicle information.

With other preferred embodiments, it is provided that the diagnostic system is configured to use the vehicle information to carry out a component-specific and/or vehicle-specific diagnosis, and/or to build or supplement a database with the corresponding information, and/or to train or validate one or more AI subsystems of the diagnostic system. This diagnostic system is self-learning.

With other preferred embodiments, it is provided that the diagnostic system is configured to determine response information, in particular a diagnostic instruction, a diagnosis result or a repair recommendation, depending on the vehicle information and to transmit it to a data processing device. This enables an interaction with a technician or the motor vehicle itself.

With other preferred embodiments, it is provided that the diagnostic system is configured to determine the response information depending on the vehicle information and using artificial intelligence algorithms. This is a particularly efficient diagnostic system.

With other preferred embodiments, it is provided that the diagnostic system is configured to retrieve component-specific and/or vehicle-specific information and/or other information from a database, in particular an external database. This advantageously eliminates the need to keep all the information required for a diagnosis of a large number of different vehicle types available in the diagnostic system. Rather, with other preferred embodiments, these can be retrieved dynamically, i.e. in particular when required, from the external database.

With other preferred embodiments, it is also conceivable to at least temporarily store the respective information in a database of the diagnostic system. Preferably, storing in a database of the diagnostic system can be carried out, for example, depending on a frequency of use of the respective data.

With other preferred embodiments, it is provided that at least one database is provided in the diagnostic system, in particular for storing component-specific and/or vehicle-specific information and/or fault codes. In this way, the dependence on an external database can be reduced or an increased interference resistance for the operation of the system can be achieved.

With other preferred embodiments, it is provided that the diagnostic system is configured to at least temporarily store a diagnostic response characterizing the course of a repair of the motor vehicle, and in particular to relate the diagnostic response to a previously issued diagnostic instruction. This advantageously enables an efficient training of the AI subsystems.

With other preferred embodiments, it is provided that the diagnostic system comprises at least one computing device which is configured to link the diagnostic data with the information about the at least one operating parameter of the motor vehicle in a diagnostic tree or a diagnostic jungle with the information about the at least one component by comparing the at least one operating parameter in a comparison with at least one reference value, in order to either determine a diagnostic instruction or to determine a diagnosis result or a repair recommendation depending on the result of the comparison. This enables an efficient assignment of the components and the vehicle information to fault probabilities in a diagnosis. It may be provided to use a manufacturer-independent and/or vehicle-independent diagnostic tree or diagnostic jungle which assigns individual components used in a plurality of motor vehicles of different manufacturers to at least one diagnostic instruction, at least one diagnosis result and/or at least one repair recommendation.

With other preferred embodiments, it is provided that at least one computing device of the diagnostic system is configured to determine the information about the probability, the reference value, the probability, the diagnostic instruction, the diagnosis result or the repair recommendation depending on the information about the at least one operating parameter by means of an artificial neural network, in particular in a system which is self-learning according to the greedy layer-wise pretraining method, in particular with many layers between an input layer and an output layer of the neural network. This is a particularly efficiently learning diagnostic system.

With other preferred embodiments, it is provided that at least one computing device of the diagnostic system is configured to determine the information about the probability, the reference value, the probability, the diagnostic instruction, the diagnosis result or the repair recommendation depending on the information about the at least one operating parameter by means of an algorithm for supervised learning, in particular by classification with logistic regression, decision forest, decision jungle, reinforced decision tree, artificial neural network, averaged perceptron, support vector method, locally deep support vector method, Bayes' point machine, and/or by means of linear regression, Bayesian linear regression, regression with decision forest, regression with reinforced decision tree, regression with artificial neural network, Poisson regression, and/or by means of anomaly detection with support vector method, principal component analysis, K-means clustering. The use of these algorithms makes the diagnostic system particularly efficient, regardless of the manufacturer or the vehicle type of the motor vehicle.

Further preferred embodiments relate to a method for processing data of a motor vehicle in a diagnostic system, wherein the diagnostic data for at least one component of a motor vehicle is accessed, wherein the diagnostic data links the information about at least one operating parameter of the motor vehicle with the information about the at least one component, wherein the information about a probability of an occurrence of a fault in the motor vehicle is evaluated depending on the diagnostic data and depending on the information about the at least one operating parameter. This makes it possible to carry out an efficient diagnosis of faults, for example, which occur during operation of the motor vehicle.

With preferred embodiments, it is provided that an expert system evaluates the diagnostic data by determining the information about the probability depending on information about an observation of a technician, or a measured value, in particular voltage, current, capacitance, inductance of a component. In this way, knowledge useful for an efficient diagnosis of faults and an evaluation of, for example, operating parameters of a motor vehicle can be processed by machine and can be provided to a data processing device, for example.

In other preferred embodiments, it is provided that algorithms of artificial intelligence, AI, evaluate the diagnostic data by determining the information about the probability depending on information about an observation of a technician, or a measured value, in particular voltage, current, capacity, inductance of a component. This can significantly increase the flexibility of the system operation and the diagnostic reliability compared to conventional systems. While conventional systems, for example, allow or suggest a sequential processing of individual fault codes or fault symptoms, the diagnostic system can carry out a diagnosis much more efficiently using AI-based algorithms, can in particular also learn from its own operation or from information obtained during operation (e.g. from the data processing device), and thus, can further improve its function.

With other preferred embodiments, data of the vehicle read out via an OBD-II interface can be received. This interface is widely used in the market and allows an efficient access to a large number of motor vehicles from different manufacturers.

With other preferred embodiments, it is provided that vehicle information of the motor vehicle is received, wherein the vehicle information comprises at least one of the following elements: vehicle identification number VIN (in German: FIN, Fahrzeug-Indentifizierungsnummer), operating data characterizing an operation of at least one component of the motor vehicle, one or more fault codes characterizing a fault of at least one component of the motor vehicle. A comparatively low bandwidth is advantageously required to transmit the vehicle information.

With other preferred embodiments, it is provided that the vehicle information is used to carry out a component-specific and/or vehicle-specific diagnosis, and/or to build or supplement a database with the respective information, and/or to train or validate one or more AI subsystems of a diagnostic system. This enables a result of the diagnosis to be dependent on other vehicles for which the diagnostic data according to the vehicle information is also true.

With other preferred embodiments, it is provided that response information, in particular a diagnostic instruction, a diagnosis result or a repair recommendation, is determined depending on the vehicle information and is transmitted to a data processing device. This enables an interaction with a technician who interacts with the vehicle to be repaired.

With other preferred embodiments, it is provided that the response information is determined depending on the vehicle information using artificial intelligence algorithms. This enables a particularly efficient diagnosis.

With other preferred embodiments, it is provided that component-specific and/or vehicle-specific information and/or other information is retrieved from a database, in particular an external database. This advantageously eliminates the need to keep all the information required for a diagnosis of a large number of different vehicle types available in the diagnostic system. Rather, with other preferred embodiments, these can be retrieved dynamically, i.e. in particular when required, from the external database. With other preferred embodiments, it is also conceivable to at least temporarily store the respective information in a database of the diagnostic system. In this way, the dependence on an external database can be reduced or an increased interference resistance for the operation of the system can be achieved.

With other preferred embodiments it is provided that component-specific and/or vehicle-specific information and/or fault codes are stored in a database of the diagnostic system. Preferably, storing in a database of the diagnostic system can be carried out, for example, depending on a frequency of use of the respective data.

With other preferred embodiments, it is provided that a diagnostic response characterizing a course of a repair of the motor vehicle is at least temporarily stored, and in particular that the diagnostic response is set in relation to a previously issued diagnostic instruction.

With other preferred embodiments, it is provided that the diagnostic data links the information about the at least one operating parameter of the motor vehicle in a diagnostic tree or a diagnostic jungle with information about the at least one component by comparing the at least one operating parameter in a comparison with at least one reference value, in order to either determine a diagnostic instruction or to determine a diagnosis result or a repair recommendation depending on the result of the comparison. This advantageously enables an efficient diagnosis.

With other preferred embodiments, it is provided that the information about the probability, the reference value, the probability, the diagnostic instruction, the diagnosis result and/or the repair recommendation is determined depending on the information about the at least one operating parameter by means of an artificial neural network, in particular in a system which is self-learning according to the greedy layer-wise pretraining method, in particular with many layers between an input layer and an output layer of the neural network. This is a particularly efficient method of self-learning artificial intelligence.

With other preferred embodiments, it is provided that the information about the probability, the reference value, the probability, the diagnostic instruction, the diagnosis result and/or the repair recommendation is determined depending on the information about the at least one operating parameter by an algorithm for supervised learning, in particular by classification with logistic regression, decision forest, decision jungle, reinforced decision tree, artificial neural network, averaged perceptron, support vector method, locally deep support vector method, Bayes' point machine, and/or by linear regression, Bayesian linear regression, regression with decision forest, regression with reinforced decision tree, regression with artificial neural network, Poisson regression, and/or by anomaly detection with support vector method, principal component analysis, K-means clustering. This enables a particularly efficient method of artificial intelligence.

Further features, possible applications and advantages of the invention are set out in the following description of exemplary embodiments of the invention, which are shown in the figures of the drawings. All described or depicted features, alone or in any combination, form the subject-matter of the invention, irrespective of their combination in the claims or their references, and irrespective of their formulation or representation in the description or in the drawings.

### IN THE DRAWINGS

FIG. 1 schematically shows a simplified block diagram of a system,

FIG. 2 schematically shows a simplified flow chart,

FIG. 3 schematically shows a simplified block diagram of a data processing device, and

FIG. 4 schematic shows steps in a method according to an embodiment.

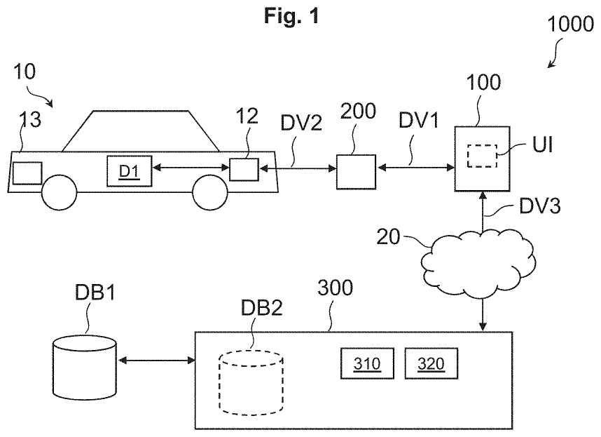

FIG. 1 schematically shows a simplified block diagram of a system 1000 according to an embodiment. System 1000 comprises a data processing device 100 for processing data D1 of a motor vehicle 10. For example, data D1 comprises information about an operating parameter of motor vehicle 10. The information about the operating parameter includes, for example, the operating parameter and/or fault codes of a control unit 12 of motor vehicle 10. Motor vehicle 10 comprises at least one component 13, for example a lambda sensor. The information about the operating parameter may be an observation of a technician or a measured value, such as voltage, current, capacitance, inductance, related to component 13.

System 1000 also comprises an interface device 200 for establishing a data link between data processing device 100 and control unit 12. The data link is preferably a wireless or cable-free data link, at least as far as the first part DV1 of the data link is concerned, which is for example designed as Bluetooth connection and/or WLAN connection or the like. The second part DV2 of the data link can also be wired, for example. With preferred embodiments, interface device 200 can be designed in the form of a so-called OBD-II dongle, for example, which is connectable to an OBD-II interface of motor vehicle 10 via a plug connection in a manner known per se. In this way, interface device 200 can be brought into data connection with control unit 12, for example.

For simple and efficient control of the operation of data processing device 100, it is provided with a user interface UI which may in particular comprise a graphic user interface and/or an acoustic user interface.

Data processing device 100 can be designed as a handheld device and/or mobile device, which allows easy handling.

Data processing device 100 can be designed as one of the following elements: Smartphone, tablet computer, laptop.

System 1000 also comprises a diagnostic system 300 for processing the data from motor vehicle 10. Diagnostic system 300 is preferably connectable to data processing device 100 via a wireless data link DV3, possibly also with the interposition of one or more private and/or public networks 20 (Internet). For example, with other preferred embodiments, wireless data link DV3 can also be implemented using a cellular mobile radio system of the third and/or fourth and/or fifth generation (3G, 4G (e.g. LTE), 5G).

With preferred embodiments, diagnostic system 300 comprises at least one expert system 310 which enables an efficient diagnosis by diagnostic system 300. With other preferred embodiments, diagnostic system 300 is configured to execute algorithms of artificial intelligence, AI. For this purpose, for example, at least one AI subsystem 320 can be provided, which, for example, comprises one or more artificial neural networks and/or other elements from the field of artificial intelligence.

With other preferred embodiments, diagnostic system 300 is configured to access an external database DB1, in particular for retrieving component-specific and/or vehicle-specific information or component-specific information concerning, for example, component 13 of motor vehicle 10.

With other preferred embodiments, diagnostic system 300 can also have its own, preferably local, database DB2.

With other preferred embodiments, diagnostic system 300 is configured to receive vehicle information of motor vehicle 10, wherein the vehicle information comprises at least one of the following elements: a vehicle identification number VIN identifying the motor vehicle, operating data characterizing an operation of at least one component of the motor vehicle, one or more fault codes characterizing a fault of at least one component of the motor vehicle.

With other preferred embodiments, diagnostic system 300 is configured to receive the vehicle information from data processing device 100. In this case, data processing device 100 is configured to read out and transmit the vehicle information, in particular via interface device 200.

With other preferred embodiments, diagnostic system 300 is configured to determine response information, in particular a diagnostic instruction, a diagnosis result or a repair recommendation, depending on the information, in particular the vehicle information, and to transmit it to data processing device 100.

With other preferred embodiments, diagnostic system 300 is configured to determine the response information depending on the information, in particular the vehicle information, using artificial intelligence algorithms.

With other preferred embodiments, diagnostic system 300 is configured to retrieve component-specific and/or vehicle-specific information and/or other information from a database, in particular external database DB1.

With other preferred embodiments, at least one database DB2 is provided in diagnostic system 300, in particular for storing component-specific and/or vehicle-specific information and/or fault codes.

With other preferred embodiments, diagnostic system 300 is configured to at least temporarily store a diagnostic response characterizing the course of a repair of the motor vehicle, and in particular to relate the diagnostic response to a previously issued diagnostic instruction.

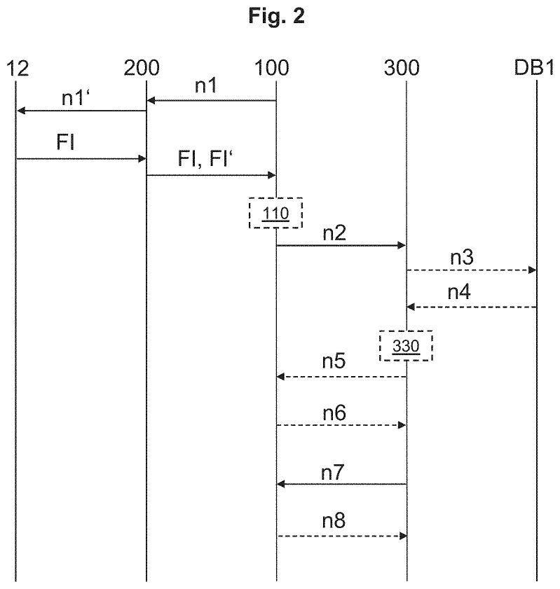

FIG. 2 schematically shows a simplified flowchart of a method according to an embodiment. Data processing device 100 transmits a first message n1 to interface device 200 (for example the OBD-II dongle which is in data communication with control unit 12 (FIG. 1) of motor vehicle 10), and interface device 200 forwards first message n1 in the form of message n1′ to control unit 12. The first message n1, n1′ may, for example, contain a control command which causes control unit 12 to output vehicle information FI to interface device 200 and/or data processing device 100. Vehicle information FI may comprise, for example, fault codes which are typically stored in fault memories of one or more control units 12 of motor vehicle 10. Alternatively or additionally, the vehicle information FI may contain one or more of the data already mentioned above (vehicle identification number and the like). With some embodiments, interface device 200 can, for example, transmit the vehicle information FI substantially unchanged to data processing device 100. With other embodiments, it may be provided that interface device 200 filters the vehicle information FI received from control unit 12 and/or processes the same in some other way, in order to transmit the thus obtained filtered and/or processed vehicle information FI′ to data processing device 100.

In an optional step 110, data processing device 100 can carry out a local processing of the received vehicle information FI, FI′, such as further filtering and/or other processing.

Data processing device 100 can also transmit the received vehicle information FI, FI′ or data derived therefrom to diagnostic system 300, for example in the form of a second message n2.

If diagnostic system 300 requires in addition to the data of second message n2 further data to carry out a diagnosis, for example component-specific and/or vehicle-specific information and/or component-specific information and the like, dialogue system 300 can retrieve this data from external database DB1 by means of an optional message n3. After receiving a corresponding optional response with the requested data from external database DB1, which is transmitted in further optional message n4, diagnostic system 300 carries out a diagnosis in a step 330. With preferred embodiments, this is done in particular using at least one artificial intelligence algorithm, for example by means of expert system 310 or by means of at least one AI subsystem 320.

If diagnostic system 300 requires in addition to the data of the second message n2 further data to carry out the diagnosis, for example observations of a technician, measurement data and the like, diagnostic system 300 can request this data by means of an optional message n5 to data processing device 100. Optional message n5 may comprise one or more diagnostic instructions. These can specify one or more test steps. For example, an observation of a technician performing a test on motor vehicle 10 is requested. For example, measurements such as voltage, current or the like at a component 13 are requested. Also the readout of vehicle information via interface 200 can be requested. After receiving a corresponding optional diagnostic response with the requested data from data processing device 100, which is transmitted in a further optional message n6, diagnostic system 300 carries out step 330 for a further diagnosis with the received data. In this way, several test steps and diagnostic steps can be instructed in order to narrow down a fault pattern.

For example, a diagnostic instruction specifies at least one test step for at least one component 13 of motor vehicle 10. The test steps may be measurement instructions, observation instructions or work step instructions for the inspection of the at least one component 13.

For example, the diagnostic response contains at least one piece of information about at least one operating parameter of motor vehicle 10.

After the execution 330 of the diagnosis, diagnostic system 300 can transmit another optional message n7 to data processing device 100 which may contain a diagnosis result or a repair recommendation, for example.

For example, such a diagnosis result or repair recommendation may contain an indication for a user of data processing device 100, specifying which component 13 of motor vehicle 10 is to be preferably replaced in order to enable an efficient repair, i.e. the elimination of the cause of the fault.

By the principle according to the embodiments, an efficient diagnosis can be advantageously carried out, wherein particularly preferably a comparatively small first number of diagnostic systems 300 enables the efficient provision of an efficient diagnosis for a comparatively large second number of data processing devices 100.

With other embodiments, it may be provided that diagnostic system 300 at least temporarily stores a diagnostic response characterizing a course of a diagnosis of motor vehicle 10, and in particular relates the diagnostic response to a previously issued diagnostic instruction n5. With other embodiments, such diagnostic responses can be transmitted to diagnostic system 300, for example, by data processing device 100 by means of optional message n6, for example depending on a user input from a technician as user of data processing device 100 which rates an effect or a quality of the diagnostic instruction from n5.

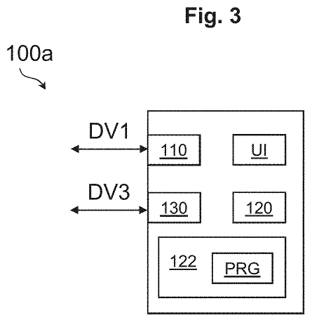

FIG. 3 schematically shows a simplified block diagram of a data processing device 100a, which can communicate with a diagnostic system 300 according to an embodiment. For example, data processing device 100 shown in FIG. 1, 2 may have the configuration shown in FIG. 3. Data processing device 100a comprises a first data interface 110 for establishing the first data link DV1 (such as Bluetooth and/or WLAN or the like) and a second data interface 130 for establishing data link DV3 to diagnostic system 300. Data processing device 100a also comprises a computing device 120 which includes, for example, at least one microcontroller and/or microprocessor and/or digital signal processor (DSP), and/or a programmable logic device (FPGA, field programmable gate array) and/or an application-specific integrated circuit (ASIC). Computing device 120 is assigned a memory device 122 which is configured to at least temporarily store a computer program PRG. Computer program PRG can be configured to execute the method, for example. The memory device 122 can, for example, comprise at least one volatile memory, in particular working memory (RAM), and/or at least one non-volatile memory, in particular read-only memory (ROM) and/or flash EEPROM memory or the like.

Computing device 120 can also be configured to provide a user interface, in particular a graphic user interface, for at least one user of data processing device 100a. In this way, diagnosis and/or repair instructions for the user can be efficiently provided, which, for example, can be kept in memory device 122 at least temporarily and/or can be retrieved by diagnostic system 300 as required.

With other preferred embodiments, it may be provided that first database DB1 and/or second database DB2 contain component-specific and/or vehicle-specific data, in particular comprising information up to a component level. Preferably, the component-specific and/or vehicle-specific data comprises a linkage of components 13 of the same component type with data of different vehicle manufacturers or vehicle types.

Diagnostic system 300 is configured to process data from motor vehicle 10. Diagnostic system 300 is configured to access diagnostic data for at least one component 13 of motor vehicle 10.

The diagnostic data links information about at least one operating parameter of motor vehicle 10 with information about the at least one component 13.

Diagnostic system 300 is configured to determine information about a probability of an occurrence of a fault in motor vehicle 10 depending on the diagnostic data and depending on the information about the at least one operating parameter.

In a preferred embodiment, diagnostic system 300 comprises at least one expert system 310 which is configured to determine the information about the probability.

In a preferred embodiment, diagnostic system 300 comprises at least one AI subsystem 320 which is configured to execute algorithms of artificial intelligence, AI, in order to determine the information about the probability.

In a preferred embodiment, diagnostic system 300 comprises at least one computing device which is configured to link the diagnostic data with the information about the at least one operating parameter of motor vehicle 10 in a diagnostic tree or a diagnostic jungle with information about the at least one component 13 by comparing the at least one operating parameter in a comparison with at least one reference value, in order to determine a diagnostic instruction, a diagnosis result or a repair recommendation depending on the result of the comparison.

In a preferred embodiment, at least one computing device of diagnostic system 300 is configured to determine the reference value, the probability, the diagnostic instruction, the diagnosis result and/or the repair recommendation depending on the information about the at least one operating parameter by means of an artificial neural network, in particular in a system which is self-learning according to the greedy layer-wise pretraining method, in particular with many layers between an input layer and an output layer of the neural network, when determining the information about the probability.

In a preferred embodiment, at least one computing device is configured to determine the reference value, the probability, the diagnostic instruction, the diagnosis result and/or the repair recommendation depending on the information about the at least one operating parameter by means of an algorithm for supervised learning known per se, in particular by classification with logistic regression, decision forest, decision jungle, reinforced decision tree, artificial neural network, averaged perceptron, support vector method, locally deep support vector method, Bayes' point machine, and/or by linear regression, Bayesian linear regression, regression with decision forest, regression with reinforced decision tree, regression with artificial neural network, Poisson regression, and/or by anomaly detection with support vector method, principal component analysis, K-means clustering, when determining the information about the probability.

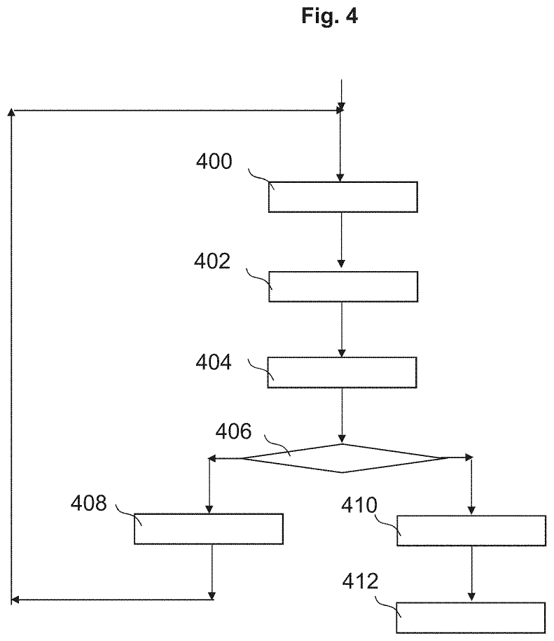

In the following, a diagnostic method is described with respect to FIG. 4.

The method is suitable for processing data of motor vehicle 10 in diagnostic system 300. The method can also be carried out in other diagnostic systems with distributed or centrally arranged computing devices.

This computing device comprises or these computing devices comprise for example at least one microcontroller and/or microprocessor and/or digital signal processor (DSP), and/or a programmable logic device (FPGA, field programmable gate array) and/or an application-specific integrated circuit (ASIC). A memory device may be assigned which is configured to at least temporarily store a computer program PRG. Computer program PRG in this example is configured to execute the method. The memory device can, for example, comprise at least one volatile memory, in particular working memory (RAM), and/or at least one non-volatile memory, in particular read-only memory (ROM) and/or flash EEPROM memory or the like.

In the method, diagnostic data for at least one component 13 of motor vehicle 10 is accessed, wherein the diagnostic data links the information about at least one operating parameter of motor vehicle 10 with information about the at least one component 13.

The method provides for the determination of information about a probability of an occurrence of a fault in the motor vehicle depending on the diagnostic data and depending on the information about the at least one operating parameter.

In a preferred embodiment, the method provides that at least one expert system 310 processes the diagnostic data to determine the information about the probability.

In a preferred embodiment, the method provides that algorithms of artificial intelligence, AI, process the diagnostic data to determine the information about the probability.

In a step 400, data of vehicle 10 is received which is read out in particular via an OBD-II interface or which was read out before step 400.

In the example, vehicle information is received as information about at least one operating parameter of motor vehicle 10, comprising at least one of the following elements: vehicle identification number, VIN (in German: FIN, Fahrzeug-Identifizierungsnummer), identifying the motor vehicle, operating data characterizing an operation of at least one component of the motor vehicle, one or more fault codes characterizing a fault of at least one component of the motor vehicle.

Subsequently, an optional step 402 is executed.

In optional step 402, component-specific and/or vehicle-specific information and/or other information is retrieved in particular from external database DB1 or from database DB2 arranged in diagnostic system 300. With regard to external database DB1, this is done as described for messages n3 and n4, for example.

After step 400 or optional step 402, a step 404 is executed.

In a step 404, when determining the information about the probability, the reference value, the probability, the diagnostic instruction, the diagnosis result and/or the repair recommendation is determined depending on the information about the at least one operating parameter by means of an artificial neural network, in particular in a system which is self-learning according to the greedy layer-wise pretraining method, in particular with many layers between an input layer and an output layer of the neural network.

Alternatively or in addition to this, when determining the information about the probability, the reference value, the probability, the diagnostic instruction, the diagnosis result and/or the repair recommendation is determined depending on the information about the at least one operating parameter by means of an algorithm for supervised learning.

In particular, the information about probability is determined by a classification with logistic regression, decision forest, decision jungle, reinforced decision tree, artificial neural network, averaged perceptron, support vector method, locally deep support vector method, Bayes' point machine, and/or by linear regression, Bayesian linear regression, regression with decision forest, regression with reinforced decision tree, regression with artificial neural network, Poisson regression, and/or by anomaly detection with support vector method, principal component analysis, or K-means clustering. In this example, these provide an adapted decision tree as a diagnostic tree.

The probability or the information about the probability that an end point of the decision tree is to be selected, is determined in the example depending on the information about at least one operating parameter, for example vehicle information, information about an observation of a technician, or the measured value, in particular voltage, current, capacitance, inductance of a component 13.

Expert system 310 can evaluate the diagnostic data by determining the information about the probability depending on information about the observation of the technician, or the measured value, especially voltage, current, capacitance, inductance of a component 13. Algorithms of artificial intelligence, AI, can evaluate the diagnostic data by determining the information about the probability depending on information about an observation of a technician or a measured value, in particular voltage, current, capacity, inductance of a component 13.

Subsequently, step 406 is executed.

In step 406, the information about a probability of an occurrence of a fault in vehicle 10 is evaluated depending on the diagnostic data and depending on the information about the at least one operating parameter.

In the example, the information about the probability of the occurrence of the fault is determined depending on information about an observation of a technician, or a measured value, in particular voltage, current, capacitance, inductance of a component 13.

In a preferred embodiment, the diagnostic data links the information about the at least one operating parameter of motor vehicle 10 in a diagnostic tree with information about the at least one component. In the example, the diagnostic tree is structured like a decision tree that was adapted in step 404. Instead, a diagnosis jungle can also be used, which is structured like a decision jungle.

The information about the probability can be a percentage. In this case, the result of the evaluation provides information about the fault with, as a percentage, the highest probability of occurrence.

The linkage of the information about the at least one operating parameter with the information about the at least one component 13 in the diagnostic data is carried out in a preferred embodiment by comparing 406 the at least one operating parameter with at least one reference value. The reference value is determined by one of the artificial intelligence algorithms or the expert system, for example depending on the vehicle information, the information about an observation of a technician, or the measured value, in particular voltage, current, capacity, inductance of a component 13.

If the at least one operating parameter and the reference value do not match, a step 408 is executed. Else, a step 410 is executed. Generally, step 408 is executed if no diagnostic instruction or repair recommendation can be determined yet.

In step 408, the vehicle information is used, for example, to carry out a component-specific and/or vehicle-specific diagnosis. It may be provided to determine a diagnosis instruction, in particular a query, depending on the vehicle information and to transmit it to data processing device 100.

Alternatively or additionally, external database DB1 or database DB2 of diagnostic system 300 is built or supplemented with the respective information in step 408.

In a preferred embodiment, one or more AI subsystems 320 of diagnostic system 300 are trained or validated.

In a preferred embodiment, it is provided that in step 408 component-specific and/or vehicle-specific information and/or fault codes are stored in database DB2 of diagnostic system 300.

Subsequently, step 400 is executed.

In step 410, response information, in particular the diagnosis result or the repair recommendation, is determined depending on the vehicle information.

In a preferred embodiment, the diagnostic tree contains in endpoints the response information, i.e. the diagnostic instruction, the diagnosis result or the repair recommendation for the fault with the highest probability.

The diagnostic instruction can also be contained in other nodes than the end nodes.

The diagnostic instruction, the diagnosis result or the repair recommendation can be stored in external database DB1 or database DB2 of the diagnostic system 300 as text, audio or video information.

Subsequently, a step 412 is executed.

In step 412, the response information, in particular the diagnosis result or the repair recommendation, is transmitted to data processing device 100. In this respect, reference is also made to messages n5 and n6.

In a preferred embodiment, a diagnostic response characterizing a course of a repair of motor vehicle 10 is stored at least temporarily. The diagnostic response is preferably set in relation to the previously issued diagnostic instruction or repair recommendation. For example, a fault pattern before the execution of the diagnostic instruction or the repair recommendation together with a fault pattern after the execution of the diagnostic instruction or the repair recommendation are used as training data for a training of expert system 310 or AI subsystem 320.

A computer program product may contain instructions that, when executed by one computer or by several distributed computers, carry out the described method. The steps of the method can be executed repeatedly. A sequence of execution of the method steps is only shown as an example. A different sequence can be chosen. Individual method steps can also be omitted for a repeated execution.

1. A diagnostic system, for processing data of a motor vehicle, comprising:
at least one processor,
configured to access diagnostic data for at least one component of the motor vehicle, the diagnostic data linking information about at least one operating parameter of the motor vehicle with information about the at least one component, and
configured to evaluate information about a probability of an occurrence of a fault in the motor vehicle depending on the diagnostic data and depending on the information about the at least one operating parameter.

2. The diagnostic system of claim 1, wherein the diagnostic system comprises at least one expert system or at least one AI subsystem, configured to evaluate the information about the probability by determining the information about the probability depending on information about an observation of a technician or a measured value.

3. The diagnostic system according to claim 1, further comprising:
a receiver configured to receive vehicle information of the motor vehicle, the vehicle information including at least one of: a vehicle identification number identifying the motor vehicle, operating data characterizing an operation of at least one component of the motor vehicle, and one or more fault codes characterizing a fault of at least one component of the motor vehicle.

4. The diagnostic system of claim 3, wherein the at least one processor is configured to at least one of
use the vehicle information to carry out at least one of a component-specific diagnosis and vehicle-specific diagnosis,
build or supplement a database with respective information, and
train or validate one or more AI subsystems of the diagnostic system.

5. The diagnostic system of claim 3, wherein the at least one processor is configured to determine response information, depending on the vehicle information, and further comprises a transmitter to transmit the response information to a data processing device.

6. The diagnostic system of claim 5, wherein the at least one processor is configured to determine the response information depending on the vehicle information, using artificial intelligence algorithms.

7. The diagnostic system of claim 1, wherein the at least one processor is configured to retrieve at least one of component-specific information vehicle-specific information and other information from a database.

8. The diagnostic system of claim 1, further comprising:
at least one database, provided in the diagnostic system, for storing at least one of component-specific information, vehicle-specific information and fault codes.

9. The diagnostic system of claim 1, further comprising:
a temporary storage device configured to at least temporarily store a diagnostic response characterizing a course of a repair of the motor vehicle.

10. The diagnostic system according to claim 1, further comprising:
at least one computing device, configured to link the diagnostic data having the information about the at least one operating parameter of the motor vehicle in a diagnostic tree or a diagnostic jungle with information about the at least one component by comparing the at least one operating parameter in a comparison with at least one reference value, in order to either determine a diagnostic instruction or to determine a diagnosis result or a repair recommendation depending on a result of the comparing.

11. The diagnostic system of claim 1, further comprising:
at least one computing device, configured to determine the information about the probability, the reference value, the probability, the diagnostic instruction, the diagnosis result or the repair recommendation depending on the information about the at least one operating parameter by way of an artificial neural network, in particular in a system which is self-learning according to the greedy layer-wise pretraining method, in particular with many layers between an input layer and an output layer of the neural network.

12. The diagnostic system of claim 1, further comprising:
at least one computing device configured to determine the information about the probability, the reference value, the probability, the diagnostic instruction, the diagnosis result or the repair recommendation depending on the information about the at least one operating parameter by way of an algorithm for supervised learning, with
logistic regression,
decision forest,
decision jungle,
reinforced decision tree,
artificial neural network,
averaged perceptron,
support vector method,
locally deep support vector method,
Bayes' point machine,
and/or by
linear regression,
Bayesian linear regression,
regression with decision forest,
regression with reinforced decision tree,
regression with artificial neural network,
Poisson regression,
and/or by anomaly detection with
support vector method,
principal component analysis,
K-means clustering.

13. A method of processing data of a motor vehicle in a diagnostic system, comprising:
accessing diagnostic data for at least one component of the motor vehicle the diagnostic data linking information about at least one operating parameter of the motor vehicle with information about the at least one component; and
evaluating information about a probability of an occurrence of a fault in the motor vehicle, depending on the diagnostic data and depending on the information about the at least one operating parameter.

14. The method of claim 13, wherein the evaluating includes at least one expert system evaluating the diagnostic data, or include algorithms of artificial intelligence evaluating the diagnostic data by determining the information about the probability depending on information about an observation of a technician or a measured value.

15. The method of claim 13, further comprising:
receiving vehicle information of the motor vehicle the vehicle information including at least one of: a vehicle identification number identifying the motor vehicle, operating data characterizing an operation of at least one component of the motor vehicle, and one or more fault codes characterizing a fault of at least one component of the motor vehicle.

16. The method of claim 15, wherein the vehicle information is used to at least one of carry out at least one of a component-specific and a vehicle-specific diagnosis; to build or supplement a database with the respective information; and to train or validate one or more AI subsystems of the diagnostic system.

17. The method of claim 15, further comprising:
determining response information depending on the vehicle information, and
transmitting the response information to a data processing device.

18. The method of claim 17, wherein the determining of the response information, includes determining the response information using artificial intelligence algorithms.

19. The method of claim 13, further comprising:
retrieving at least one of component-specific information, vehicle-specific information and other information from a database.

20. The method of claim 13, further comprising:
storing, at least one of component-specific information, vehicle-specific information and fault codes in a database of the diagnostic system.

21. The method of claim 13, further comprising:
at least temporarily storing a diagnostic response characterizing a course of a repair of the motor vehicle.

22. The method of claim 13, further comprising: linking, via the diagnostic data, the information about the at least one operating parameter of the motor vehicle in a diagnostic tree or a diagnostic jungle with information about the at least one component by comparing the at least one operating parameter in a comparison with at least one reference value, to either determine a diagnostic instruction or to determine a diagnosis result or a repair recommendation depending on a result of the comparison.

23. The method of claim 13, further comprising:
determining at least one of the information about the probability, the reference value, the probability, the diagnostic instruction, the diagnosis result and the repair recommendation, depending on the information about the at least one operating parameter, via an artificial neural network.

24. The method of claim 13, further comprising:
determining at least one of the information about the probability, the reference value, the probability, the diagnostic instruction, the diagnosis result and the repair recommendation, depending on the information about the at least one operating parameter by means of an algorithm for supervised learning, by classification with
logistic regression,
decision forest,
decision jungle,
reinforced decision tree,
artificial neural network,
averaged perceptron,
support vector method,
locally deep support vector method,
Bayes' point machine,
and/or by
linear regression,
Bayesian linear regression,
regression with decision forest,
regression with reinforced decision tree,
regression with artificial neural network,
Poisson regression,
and/or by anomaly detection with
support vector method,
principal component analysis,
K-means clustering.

25. A non transitory computer readable medium storing a computer program including instructions, which when executed by a computer or distributed computers, carry out the method of claim 13.

26. A non-transitory computer program product storing a computer program, the computer program including instructions, which when executed by a computer or distributed computers, carry out the method of claim 13.

27. The diagnostic system of claim 2, wherein the information about an observation of a technician or a measured value includes at least one of voltage, current, capacitance, and inductance of a component.

28. The method of claim 17, wherein the response information includes at least one of a diagnostic instruction, a diagnosis result, or a repair recommendation.
